(19) United States
(12) Patent Application Publication
(10) Pub. No.: US 2009/0034207 A1
(43) Pub. Date: Feb. 5, 2009

(54) CASING

(75) Inventors: Lin-Wei Chang, Taipei City (TW); Yi-Chun Shih, Taipei City (TW)

Correspondence Address: J C PATENTS, INC., 4 VENTURE, SUITE 250, IRVINE, CA, 92618, US

(73) Assignee: INVENTEC CORPORATION, Taipei City (TW)

(21) Appl. No.: 11/831,457

(22) Filed: Jul. 31, 2007

(51) Int. Cl. H05K 5/00

(52) U.S. Cl. 361/724

(57) ABSTRACT

A casing including a carrying frame and at least one detachable carrying component is provided. The carrying frame includes two sidewalls and a base. The sidewalls face each other, and each sidewall has a first sliding connection portion. The sidewalls are respectively connected to the base, and the sidewalls and the base form an accommodating space. The detachable carrying component has two second sliding connection portions, and the second sliding connection portions are suitable for being slidingly connected to the first sliding connection portions respectively. The detachable carrying component is suitable for being slidingly disposed in the accommodating space along a gravitational direction. The method of assembling the casing is simpler.

### BACKGROUND OF THE INVENTION

1. Field of the Invention

The present invention generally relates to an assembly, and more particularly, to the assembly of a casing.

2. Description of Related Art

With the many innovations of computer technologies, the computing efficiency of a microprocessor is increased significantly so that the computing speed of a computer increases at an accelerating pace while the price of a computer drops substantially. At present, most computers are capable of performing normal word processing task and completing simple computations. However, ordinary computers are still inadequate for jobs that require a lot of computation. Therefore, a high-speed and operationally efficient personal super computer (PSC) has been developed.

In a PSC, the user plugs in several motherboards into a computer casing. The processors on these motherboards are utilized to increase the operational efficiency of the PSC so that the PSC is capable of executing several tens or hundreds of billion floating-point-operations per second. Although the number of floating-point-operations executed by the PSC per unit time still has not reached the level of a genuine super computer, the PSC is already several tens of thousand times faster than an ordinary personal computer.

In general, when a conventional PSC is assembled, the motherboards are inserted horizontally into the casing of a PSC via the front, the rear or the side of the casing. Normally, the user needs to apply an opposing force to the casing so as to counteract the user's action of inserting the motherboard so that the casing will not slide on the desktop or the floor. In addition, if the motherboards are inserted into the casing via the front, the rear or the side of the casing, the number of fans and their locations are affected.

### SUMMARY OF THE INVENTION

The present invention is directed to a casing having a simpler method of assembling.

The present invention provides a casing including a carrying frame and at least one detachable carrying component. The carrying frame includes two sidewalls and a base. The sidewalls face each other, and each sidewall has a first sliding connection portion. The sidewalls are respectively connected to the base, and the sidewalls and the base form an accommodating space. The detachable carrying component has two second sliding connection portions, and the second sliding connection portions are suitable for being slidingly connected to the first sliding connection portions respectively. The detachable carrying component is suitable for being slidingly disposed in the accommodating space along a gravitational direction.

In an embodiment of the present invention, the detachable carrying component includes a first carrying plate, wherein the second sliding connection portions are respectively connected to a first side and a second side of the first carrying plate. When the detachable carrying component is slidingly disposed in the accommodating space, the first carrying plate stands substantially erect on the base, and the first side and the second side are substantially parallel to the gravitational direction.

In an embodiment of the present invention, the detachable carrying component further includes a top portion. The top portion includes a top plate and two holding portions. The top plate is connected to a third side of the first carrying plate. When the detachable carrying component is slidingly disposed in the accommodating space, the third side is distant from the base and a top surface of each sidewall interferes with the top plate. The holding portions are connected to the top plate. When the detachable carrying component is slidingly disposed in the accommodating space, the holding portions respectively maintain a gap with the top surfaces.

In an embodiment of the present invention, the detachable carrying component further includes a second carrying plate connected to a fourth side of the first carrying plate. When the detachable carrying component is slidingly disposed in the accommodating space, the fourth side is adjacent to the base and the second carrying plate is disposed on the base.

In an embodiment of the present invention, each first sliding connection portion may be a track, and each second sliding connection portion may be a side plate.

Because the detachable carrying component is suitable for being slidingly disposed into the accommodating space in the gravitational direction, the user only apply a force to the detachable carrying component in a direction opposite to the gravitational direction to remove the detachable carrying component from the accommodating space. Therefore, the casing of the present invention is easy to assemble and dissemble.

In order to make the aforementioned and other objects, features and advantages of the present invention comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is an explosion diagram of a casing according to an embodiment of the present invention.

FIG. 2 is a diagram showing the detachable carrying component of FIG. 1 slidingly disposed in an accommodating space.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

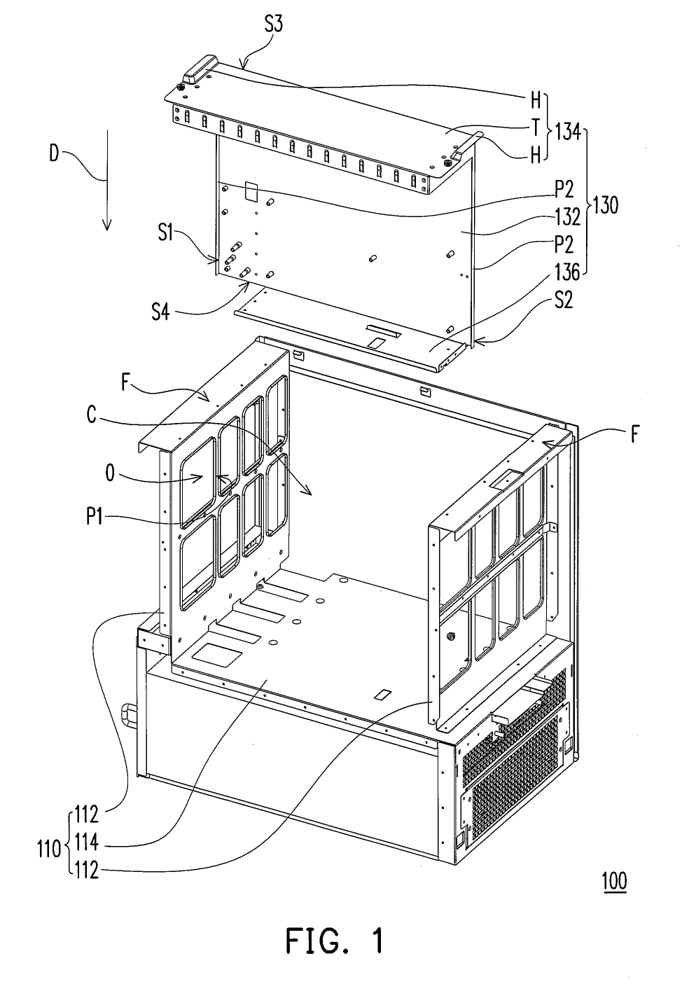

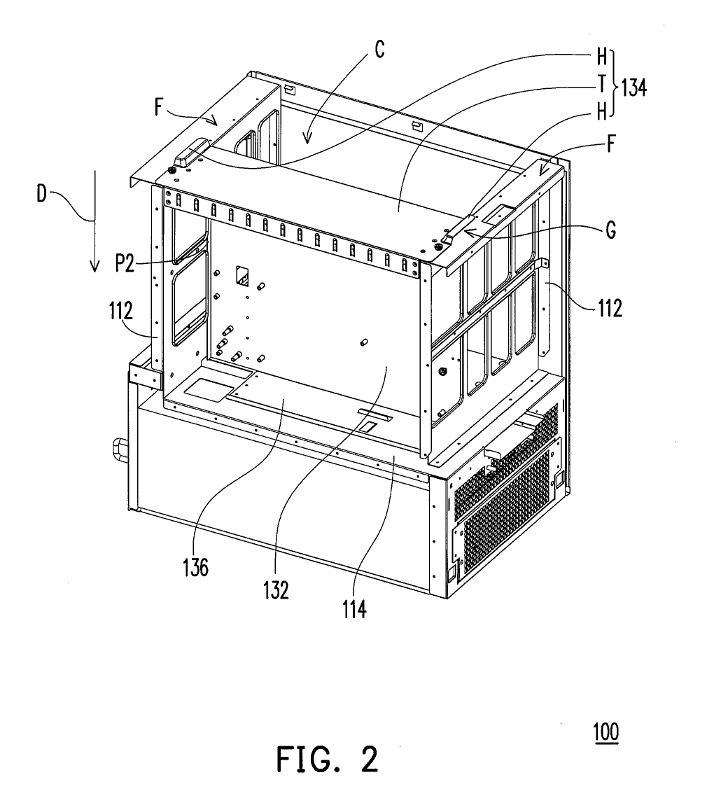

FIG. 1 is an explosion diagram of a casing according to an embodiment of the present invention. FIG. 2 is a diagram showing the detachable carrying component of FIG. 1 slidingly disposed in an accommodating space. As shown in FIGS. 1 and 2, the casing 100 (for example, applied to a PSC) includes a carrying frame 110 and at least one detachable carrying component 130 (one is shown in FIG. 1). The carrying frame 110 includes two sidewalls 112 and a base 114. The sidewalls 112 face each other, and each sidewall 112 has a first sliding connection portion P1. The sidewalls 112 are respectively connected to the base 114, and the sidewalls 112 and the base 114 form an accommodating space C. The detachable carrying component 130 has two second sliding connection portions P2. The second sliding connection portions P2 are suitable for being slidingly connected to the first sliding connection portions P1 respectively, and the detachable carrying component 130 is suitable for being slidingly disposed in the accommodating space C along a gravitational direction D.

Because the detachable carrying component 130 is suitable for being slidingly disposed in the accommodating space C along the gravitational direction D, the user only apply a force to the detachable carrying component 130 in a direction opposite to the gravitational direction D to remove the detachable carrying component 130 from the accommodating space C. Therefore, the casing 100 of the present invention is easy to assemble and dissemble.

In the present embodiment, each first sliding connection portion P1 may be a track, and each second sliding connection portion P2 may be a side plate. The first sliding connection portion P1 of each sidewall 112 is formed when holes O are punched in the sidewalls 112. In addition, a plurality of fans (not shown) may be disposed at the holes O of the sidewalls 112, and the fans are located outside the accommodating space C. Therefore, the assembling and disassembling of the detachable carrying component 130 will not interfere with the fans.

In the present embodiment, the detachable carrying component 130 includes a first carrying plate 132, a top portion 134 and a second carrying plate 136. The first carrying plate 132, the top portion 134, the second carrying plate 136 and the second sliding connection portions P2 of the present embodiment may be formed integrally. The second sliding connection portions P2 are respectively connected to a first side S1 of the first carrying plate 132 and a second side S2 of the first carrying plate 132. When the detachable carrying component 130 is slidingly disposed in the accommodating space C, the first carrying plate 132 stands substantially erect on the base 114, and the first side S1 and the second side S2 are substantially parallel to the gravitational direction D.

In the present embodiment, the top portion 134 includes a top plate T and two holding portions H. The top plate T is connected to a third side S3 of the first carrying plate 132, and the holding portions H are connected to the top plate T. When the detachable carrying component 130 is slidingly disposed in the accommodating space C, the third side S3 of the first carrying pate 132 is distant from the base 114. Moreover, a top surface F of each sidewall 112 of the carrying frame 110 interferes with the top plate T. In addition, when the detachable carrying component 130 is slidingly disposed in the accommodating space C, a gap G is maintained between each of the top surfaces F and the corresponding holding portion H. It should be noted that, the holding portions H and the top plate T might be formed integrally in the present embodiment. However, in another embodiment, each holding portion H may be a handle assembled to the top plate T, for example, according to the requirements of the designer.

The second carrying plate 136 of the present embodiment is connected to a fourth side S4 of the first carrying plate 132. When the detachable carrying component 130 is slidingly disposed in the accommodating space C, the fourth side S4 of the first carrying plate 132 is adjacent to the base 114 and the second carrying plate 136 is disposed on the base 114.

When a user needs to install or change component parts, the user can grip the holding portions H and pull the detachable carrying component 130 from the accommodating space C. Next, the user can assemble motherboards (not shown) or other component parts (not shown) to the first carrying plate 132 or the second carrying plate 136 of the detachable carrying component 130. Thereafter, the user can grip the holding portions H such that the detachable carrying component 130 is slidingly disposed in the accommodating space C along the gravitational direction D.

Here, it should be said that one detachable carrying component 130 is used as an example in the present embodiment. However, the user may dispose another or multiple of detachable carrying components 130 in the accommodating space C. When a computer motherboard or other component parts are disposed on each detachable carrying component 130 and the computer motherboards and component parts operate, the top plate T of each detachable carrying component 130 acts as a shield to prevent electromagnetic interference (EMI) from occurring between the detachable carrying components 130 where the motherboards or component parts are disposed.

In summary, the casing of the present invention has at least the following advantages:

1. Since the detachable carrying component is suitable for being slidingly disposed in the accommodating space along the gravitational direction, the user only apply a force to the detachable carrying component in a direction opposite to the gravitational direction to remove the detachable carrying component from the accommodating space. Therefore, the casing of the present invention is easy to assemble and dissemble.

2. Because multiple fans may be disposed on the sidewalls of the casing and located outside the accommodating space, the detachable carrying component may be assembled or dissembled without interfering with the fans.

3. When the casing of the present invention includes several detachable carrying components, the top plate of each detachable carrying component may act as a shield to prevent electromagnetic interference from occurring between these detachable carrying components where the motherboards or component parts are disposed.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A casing, comprising:
a carrying frame, comprising:
two sidewalls, wherein the sidewalls face each other and each sidewall has a first sliding connection portion; and
a base, wherein the sidewalls are respectively connected to the base and the sidewalls and the base form an accommodating space; and
at least one detachable carrying component, having two second sliding connection portions, wherein the second sliding connection portions are suitable for being slidingly connected to the first sliding connection portions respectively, and the detachable carrying component is suitable for being slidingly disposed in the accommodating space along a gravitational direction.

2. The casing according to claim 1, wherein the detachable carrying component comprises a first carrying plate, wherein the second sliding connection portions are respectively connected to a first side and a second side of the first carrying plate, and when the detachable carrying component is slidingly disposed in the accommodating space, the first carrying plate stands substantially erect on the base, and the first side and the second side are substantially parallel to the gravitational direction.

3. The casing according to claim 2, wherein the detachable carrying component comprises a top portion, the top portion comprising:
a top plate, connected to a third side of the first carrying plate, wherein the third side is distant from the base, and a top surface of each sidewall interferes with the top plate when the detachable carrying component is slidingly disposed in the accommodating space; and
two holding portions, connected to the top plate, wherein the holding portions respectively maintain a gap with the top surfaces when the detachable carrying component is slidingly disposed in the accommodating space.

4. The casing according to claim 2, wherein the detachable carrying component further comprises a second carrying plate connected to a fourth side of the first carrying plate, and when the detachable carrying component is slidingly disposed in the accommodating space, the fourth side is adjacent to the base and the second carrying plate is disposed on the base.

5. The casing according to claim 1, wherein each of the first sliding connection portions is a track, and each of the second sliding connection portions is a side plate.
